(19) United States
(12) Patent Application Publication
(10) Pub. No.: US 2022/0059324 A1
(43) Pub. Date: Feb. 24, 2022

(54) SUBSTRATE TREATING APPARATUS

(71) Applicant: PSK INC., Gyeonggi-do (KR)

(72) Inventors: Jong-Chan LEE, Gyeonggi-do (KR); Ju-Young PARK, Gyeonggi-do (KR); Song-I HAN, Gyeonggi-do (KR); Seong-Min NAM, Gyeonggi-do (KR)

(21) Appl. No.: 17/400,271

(22) Filed: Aug. 12, 2021

(30) Foreign Application Priority Data
Aug. 24, 2020 (KR) 10-2020-0106340

(51) Int. Cl. H01J 37/32; H01L 21/683

(52) U.S. Cl. CPC H01J 37/32449; H01L 21/6838; H01J 37/32715; H01J 2237/334; H01J 2237/2007; H01J 37/32082; H01J 37/32568

(57) ABSTRACT

The inventive concept provides a substrate treating apparatus. The substrate treating apparatus includes a housing, a support unit including a chuck that supports a substrate, a gas supply unit, and a dielectric plate that faces an upper surface of the substrate supported by the chuck, a height of a lower surface of a central area of the dielectric plate and a height of a lower surface of an edge area of the dielectric plate are different, and a height of an upper surface of a central area of the chuck and a height of an upper surface of an edge area of the chuck are different.

### CROSS-REFERENCE TO RELATED APPLICATIONS

A claim for priority under 35 U.S.C. § 119 is made to Korean Patent Application No. 10-2020-0106340 filed on Aug. 24, 2020, in the Korean Intellectual Property Office, the entire contents of which are hereby incorporated by reference.

### BACKGROUND

Embodiments of the inventive concept described herein relate to a substrate treating apparatus.

Plasma refers to a gaseous state in which ions, radicals, electrons, or the like are ionized, and is generated by a very high temperature, a strong electric field, or a radio frequency (RF) electromagnetic field. A semiconductor device manufacturing process includes an ashing or etching process of removing a film on a substrate by using plasma. The ashing or etching process is performed as ions or radical particles contained in plasma collide or react with a film on a substrate. A process of treating a substrate by using plasma is performed in various schemes. Among them, a bevel etching apparatus that treats an edge area of a substrate delivers plasma to the edge area of the substrate to treat the edge area.

FIG. 1 is a view illustrating a general bevel etching apparatus that performs a bevel etching process. Referring to FIG. 1, the general bevel etching apparatus includes a chuck 1100, an insulation ring 1200, a lower electrode 1300, a dielectric plate 1900, and an upper electrode 1500. The chuck 1100 has a seating surface, on which the substrate “W” is seated, and is connected to a power source 1110. The insulation ring 1200 may be configured to surround the chuck 1100 when viewed from a top. Furthermore, the lower electrode 1300 has a shape that surrounds the insulation ring 1200 when viewed from the top. The insulation ring 1200 is provided between the lower electrode 1300 and the chuck 1100, and spaces the lower electrode 1300 and the chuck 1100 apart from each other. The dielectric plate 1900 is disposed to face an upper surface of the substrate “W” supported by the chuck 1100. Furthermore, a discharge hole, through which an inert gas (GA) is discharged, is formed at a central area of the dielectric plate 1900. The upper electrode 1500 is disposed to face the lower electrode 1300, and is spaced apart from the dielectric plate 1900. A gap space, by which the dielectric plate 1900 and the upper electrode 1500 are spaced apart from each other, may function as a discharge hole, through which a process gas GB is discharged.

In a general bevel etching apparatus, when the edge area of the substrate “W” is treated, the inert gas GA is discharged through a discharge hole formed in the dielectric plate 1900, and the process gas GB is discharged to the gap space, by which the dielectric plate 1900 and the upper electrode 1500 are spaced apart from each other. The inert gas GA is supplied to a central area of the upper surface of the substrate “W”, and the process gas GB is supplied to an edge area of the upper surface of the substrate “W”. The process gas GB supplied to the edge area of the upper surface of the substrate “W” is excited into a plasma “P” state by an electromagnetic field generated by the upper electrode 1500 and the lower electrode 1300. Furthermore, the inert gas GA supplied to the central area of the upper surface of the substrate “W” flows in a direction that faces the edge area from the central area of the substrate “W”. Accordingly, the process gas GB is restrained from entering the central area of the substrate “W”. That is, the general bevel etching apparatus mainly generates plasma “P” in the edge area of the substrate “W” by supplying the inert gas GA to the central area of the substrate “W”.

The general bevel etching apparatus supplies the inert gas GA to the central area of the substrate “W” as described above. Accordingly, the process gas GB supplied to the edge area of the substrate “W” is restrained from entering the central area of the substrate “W”. However, when a flow rate of the inert gas GA supplied to the central area of the substrate “W” is low, the process gas GB is introduced into the central area of the substrate “W”, whereby a treatment efficiency for the edge area of the substrate “W” deteriorates and the central area of the substrate “W” also may be treated by plasma “P”. In order to prevent this, a measure of increasing the flow rate of the inert gas GA may be considered, but in this case, a consumption of the inert gas GA may be increased, a ratio of the process gas GB per unit volume may be reduced in the edge area of the substrate “W”, and the treatment efficiency for the edge area of the substrate “W” also may deteriorate.

### SUMMARY

Embodiments of the inventive concept provide a substrate treating apparatus that may efficiently treat a substrate.

Embodiments of the inventive concept also provide a substrate treating apparatus that may minimize a process gas supplied to an edge area of a substrate from being introduced into a central area of the substrate even though a flow rate of an inert gas supplied to the central area of the substrate is not increased.

Embodiments of the inventive concept also provide a substrate treating apparatus that may minimize a treatment efficiency for an edge area of a substrate from deteriorating as a ratio of a process gas per unit volume deteriorates in the edge area of the substrate.

The problems that are to be solved by the inventive concept are not limited to the above-mentioned problems, and the unmentioned problems will be clearly understood by those skilled in the art to which the inventive concept pertains from the specification and the accompanying drawings.

The inventive concept provides a substrate treating apparatus. The substrate treating apparatus includes a housing having a treatment space, a support unit including a chuck that supports a substrate in the treatment space, a gas supply unit including a first gas supply part that supplies an inert gas to a central area of the substrate supported by the chuck, and a second gas supply part that supplies a process gas excited into a plasma state to an edge area of the substrate supported by the chuck, and a dielectric plate that faces an upper surface of the substrate supported by the chuck, a height of a lower surface of a central area of the dielectric plate and a height of a lower surface of an edge area of the dielectric plate are different, and a height of an upper surface of a central area of the chuck and a height of an upper surface of an edge area of the chuck are different.

According to an embodiment, the height of the lower surface of the central area of the dielectric plate may be higher than the height of the lower surface of the edge area of the dielectric plate.

According to an embodiment, the height of the upper surface of the central area of the chuck may be lower than the height of the upper surface of the edge area of the chuck are different.

According to an embodiment, the height of the lower surface of the central area of the dielectric plate may be higher than the height of the lower surface of the edge area of the dielectric plate, and the height of the upper surface of the central area of the chuck may be lower than the height of the upper surface of the edge area of the chuck.

According to an embodiment, the upper surface of the chuck may be concave such that the height of the upper surface of the central area of the chuck is lower than the height of the upper surface of the edge area of the chuck.

According to an embodiment, the lower surface of the dielectric plate may be concave such that the height of the lower surface of the central area of the dielectric plate is higher than the height of the lower surface of the edge area of the dielectric plate.

According to an embodiment, the lower surface of the dielectric plate may be stepped such that the height of the lower surface of the central area of the dielectric plate is higher than the height of the lower surface of the edge area of the dielectric plate.

According to an embodiment, the dielectric plate may include a recess that is recessed in a direction that faces the lower surface of the dielectric plate from the upper surface of the dielectric plate, and at least one ejection hole that extends from the recess to the lower surface of the dielectric plate, and through which the inert gas supplied by the first gas supply part flows.

According to an embodiment, the substrate treating apparatus may include a base provided between the dielectric plate and a ceiling of the housing, the recess and the base may be combined with each other to form a buffer space, and the buffer space may be communicated with the ejection hole.

According to an embodiment, the first gas supply part may supply the process gas into the buffer space.

According to an embodiment, the ejection hole may have a diameter of 1.5 mm to 3.0 mm.

According to an embodiment, the support unit may include an absorption line that absorbs the lower surface of the substrate supported by the chuck, and a pressure reduction member connected to the absorption line.

According to an embodiment, the substrate treating apparatus may further include an upper electrode that surrounds the dielectric plate when viewed from a top, and the support unit includes a lower electrode that surrounds the chuck when viewed from the top, and that faces the upper electrode.

The inventive concept provides a substrate treating apparatus. The substrate treating apparatus includes a housing having a treatment space, a support unit including a chuck that supports a substrate in the treatment space, a gas supply unit including a first gas supply part that supplies an inert gas to a central area of the substrate supported by the chuck, and a second gas supply part that supplies a process gas excited into a plasma state to an edge area of the substrate supported by the chuck, and a dielectric plate that faces an upper surface of the substrate supported by the chuck, and a lower surface of the dielectric plate may be concave such that a height of a lower surface of a central area of the dielectric plate is higher than a height of a lower surface of an edge area of the dielectric plate.

According to an embodiment, a height of an upper surface of a central area of the chuck may be lower than a height of an upper surface of an edge area of the chuck.

According to an embodiment, an upper surface of the chuck may be concave such that the height of the upper surface of the central area of the chuck is lower than the height of the upper surface of the edge area of the chuck.

According to an embodiment, the support unit may include an absorption line that absorbs a lower surface of the substrate supported by the chuck, and a pressure reduction member connected to the absorption line.

According to an embodiment, the substrate treating apparatus may further include an upper electrode that surrounds the dielectric plate when viewed from a top, and a lower electrode that surrounds the chuck when viewed from the top, and that faces the upper electrode.

According to an embodiment, the chuck may be connected to an RF power source, and the upper electrode and the lower electrode are grounded.

According to an embodiment, the support unit may further include an insulation ring provided between the lower electrode and the chuck, and the insulation ring may have a stepped shape, a height of an upper surface of an inner area of which is higher than a height of an upper surface of an outer area thereof.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view schematically illustrating a general structure of a general bevel etching apparatus;

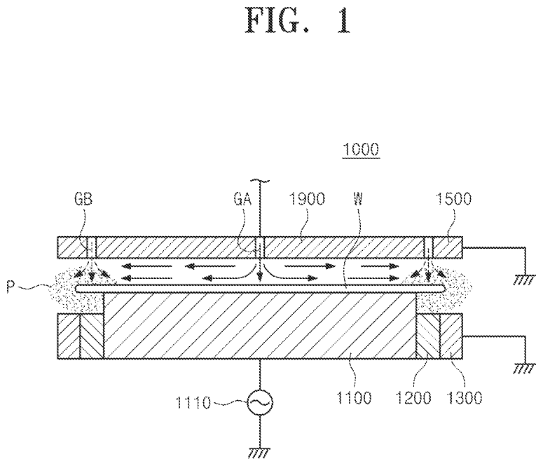

FIG. 2 is a view schematically illustrating a substrate treating facility according to an embodiment of the inventive concept;

FIG. 3 is a view illustrating an embodiment of a substrate treating apparatus provided in a process chamber of FIG. 2;

FIG. 4 is a view illustrating a state, in which the substrate treating apparatus of FIG. 3 performs a plasma treatment process; and

FIG. 5 is a view illustrating a substrate treating apparatus according to another embodiment of the inventive concept.

### DETAILED DESCRIPTION

Hereinafter, exemplary embodiments of the inventive concept will be described in detail with reference to the accompanying drawings so that those skilled in the art to which the inventive concept pertains may easily carry out the inventive concept. However, the inventive concept may be implemented in various different forms, and is not limited to the embodiments. Furthermore, in a description of the embodiments of the inventive concept, a detailed description of related known functions or configurations will be omitted when they make the essence of the inventive concept unnecessarily unclear. In addition, the same reference numerals are used for parts that perform similar functions and operations throughout the drawings.

The expression of ‘including’ some elements may mean that another element may be further included without being excluded unless there is a particularly contradictory description. In detail, the terms “including” and “having” are used to designate that the features, the numbers, the steps, the operations, the elements, the parts, or combination thereof described in the specification are present, and may be understood that one or more other features, numbers, step, operations, elements, parts, or combinations thereof may be added.

The terms of a singular form may include plural forms unless otherwise specified. Furthermore, in the drawings, the shapes and sizes of the elements may be exaggerated for clearer description.

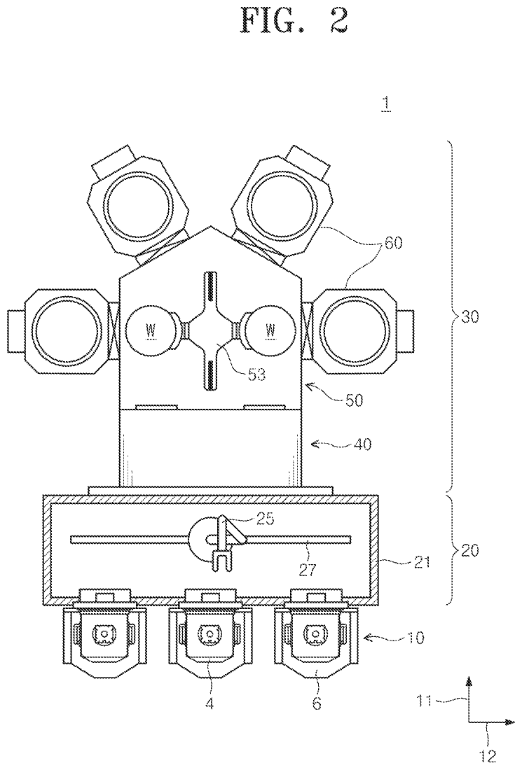

Hereinafter, embodiments of the inventive concept will be described in detail with reference to FIGS. 2 to 5.

FIG. 2 is a view schematically illustrating a substrate treating facility according to an embodiment of the inventive concept. Referring to FIG. 2, a substrate treating facility 1 has an equipment front end module (EFEM) 20 and a treatment module 30. The equipment front end module 20 and the treatment module 30 are disposed in one direction.

The equipment front end module 20 has a load port 10 and a feeding frame 21. The load port 10 is disposed in front of the equipment front end module 20 in a first direction 11. The load port 10 has a plurality of supports 6. The supports 6 are disposed in a row in a second direction 12, and substrates “W”, which are to be provided to a process and carriers 4 (for example, cassettes or FOUPs), in which the substrates “W”, the processes of which have been executed, are seated in the supports 6. Substrates “W”, which are be provided to processes, and substrate “W”, the processes of which have been executed, are received in the carriers 4. The feeding frame 21 is disposed between the load port 10 and a treatment module 30. The feeding frame 21 includes a first feeding robot 25 disposed in the interior thereof and configured to feed a substrate “W” between the load port 10 and the treatment module 30. The first feeding robot 25 moves along a feeding rail 27 provided in the second direction 12 and feeds a substrate “W” between the carrier 4 and the treatment module 30.

The treatment module 30 includes a load lock chamber 40, a transfer chamber 50, and a process chamber 60. The treatment module 30 may receive the substrate “W” from the equipment front end module 20, and may treat the substrate “W”.

The load lock chamber 40 is disposed adjacent to the feeding frame 21. As an example, the load lock chamber 40 may be disposed between the transfer chamber 50 and the equipment front end module 20. The load lock chamber 40 provides a space in which a substrate “W”, which is to be provided to a process, stands by before the substrate “W” is fed to the process chamber 60 or before the substrate “W”, a process of which has been executed, is fed to the equipment front end module 20.

The transfer chamber 50 may transfer the substrate “W”. The transfer chamber 50 is disposed adjacent to the load lock chamber 40. The transfer chamber 50 has a body that is polygonal when viewed from the top. Referring to FIG. 2, the transfer chamber 50 has a body that is pentagonal when viewed from the top. The load lock chamber 40 and a plurality of process chambers 60 are disposed outside the body along a circumference of the body. Passages (not illustrated) through which the substrate “W” is introduced and extracted are formed in side walls of the body, and the passages connect the transfer chamber 50 and the load lock chamber 40 or the process chambers 60. Each of the passages is provided with a door (not illustrated) that seals the interior of the passage by opening and closing the passage. A second feeding robot 53 that feeds the substrate “W” between the load lock chamber 40 and the process chambers 60 is disposed in an interior space of the transfer chamber 50. The second feeding robot 53 feeds an untreated substrate that stands by in the load lock chamber 40 to the process chamber 60 or feeds a substrate “W”, a process of which has been executed, to the load lock chamber 40. Furthermore, the substrate “W” is fed between the process chambers 60 to sequentially provide the substrate “W” to the plurality of process chambers 60. As illustrated in FIG. 2, when the transfer chamber 50 has a pentagonal body, the load lock chamber 40 is disposed on a side wall that is adjacent to the equipment front end module 20 and the process chambers 60 are continuously disposed on the remaining side walls. The transfer chamber 50 may be provided in various forms according to the process module required, as well as in the above-described shape.

The process chamber 60 may be disposed adjacent to the transfer chamber 50. The process chambers 60 are disposed along the circumference of the transfer chamber 50. The plurality of process chambers 60 may be provided. A process may be performed on the substrate “W” in each of the process chamber 60. The process chamber 60 receives a substrate “W” from the second feeding robot 53 and executes a process, and provides the substrate “W”, the process of which has been executed, to the second feeding robot 53. The processes executed in the process chambers 60 may be different.

Hereinafter, a substrate treating apparatus that performs a plasma process in the process chamber 60 will be described below. Furthermore, it will be described as an example that the substrate treating apparatus which will be described below may perform a plasma treatment process on an edge area of the substrate in the process chamber 60. However, the inventive concept is not limited thereto, but the substrate treating apparatus which will be described below may be applied to various chambers that treat a substrate in the same or similar ways. Furthermore, the substrate treating apparatus may be applied to various chambers that perform a plasma treatment process on a substrate in the same or similar ways.

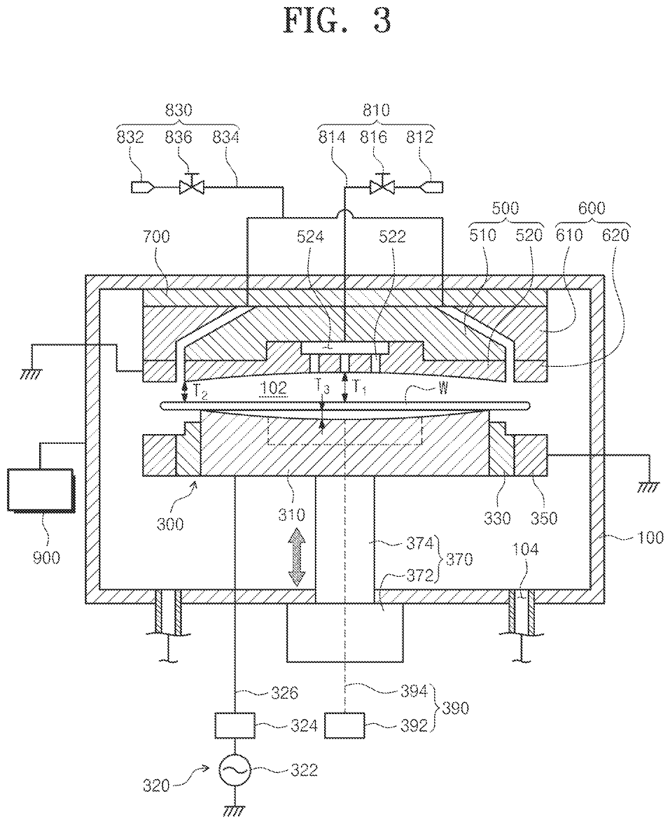

FIG. 3 is a view illustrating an embodiment of a substrate treating apparatus provided in a process chamber of FIG. 2. Referring to FIG. 3, a substrate treating apparatus provided in the process chamber 60 may perform a specific process on a substrate “W” by using plasma. As an example, the substrate treating apparatus may etch or ash a film on the substrate “W”. The film may be various kinds of films, such as a poly silicon film, a silicon oxide film, and a silicon nitride film. Furthermore, the film may be a natural oxide film or an oxide film produced chemically. Furthermore, the film may be a by-product that is generated in a process of treating the substrate “W”. Furthermore, the film may be impurities that are attached to and/or reside on the substrate “W”.

The substrate treating apparatus may perform a plasma process on the substrate “W”. For example, the substrate treating apparatus may supply a process gas and treat the substrate “W” by generating plasma from the supplied process gas. The substrate treating apparatus may supply a process gas and treat an edge area of the substrate “W” by generating plasma from the supplied process gas. Hereinafter, it will be described as an example that the substrate treating apparatus is a bevel etching apparatus that performs an etching treatment on the edge area of the substrate “W”.

The substrate treating apparatus may include a housing 100, a support unit 300, a dielectric plate unit 500, an upper electrode unit 600, a temperature adjusting plate 700, a gas supply unit 800, and a controller 900.

The housing 100 may have a treatment space 102 in an interior thereof. An opening (not illustrated) may be formed on one surface of the housing 100. The substrate “W” may be carried into or out of the treatment space 102 of the housing 100 through the opening formed in the housing 100. The opening may be opened and closed by an opening/closing member such as a door (not illustrated). When the opening of the housing 100 is opened and closed by the opening/closing member, the treatment space 102 of the housing 100 may be isolated from the outside. Furthermore, an atmosphere of the treatment space 102 of the housing 100 may be adjusted to a low pressure that is close to vacuum after the treatment space 102 is isolated from the outside. Furthermore, the housing 100 may be formed of a material including a metal. Furthermore, a surface of the housing 100 may be coated with an insulating material.

Furthermore, an exhaust hole 104 may be formed on a bottom surface of the housing 100. Plasma P generated in the treatment space 102 or gases G1 and G2 supplied to the treatment space 102 may be exhausted to the outside through the exhaust hole 104. Furthermore, the by-products generated in the process of treating the substrate “W” by using the plasma P may be exhausted to the outside through the exhaust hole 104. Furthermore, the exhaust hole 104 may be connected to an exhaust line (not illustrated). The exhaust line may be connected to a pressure reducing member that reduces pressure. The pressure reducing member may reduce a pressure in the treatment space 102 through the exhaust line.

The support unit 300 may support the substrate “W” in the treatment space 102. The support unit 300 may include a chuck 310, a power source member 320, an insulation ring 330, a lower electrode 350, a driving member 370, and an absorption member 390.

The chuck 310 may have a support surface that supports the substrate “W”. The chuck 310 may have a circular shape when viewed from a top. The chuck 310 may have a diameter that is smaller than that of the substrate “W” when viewed from the top. Accordingly, a central area of the substrate “W” supported by the chuck 310 may be seated on the support surface of the chuck 310, and an edge area of the substrate “W” may not contact the support surface of the chuck 310.

A heating unit (not illustrated) may be provided in an interior of the chuck 310. The heating unit (not illustrated) may heat the chuck 310. The heating unit may be a heater. Furthermore, a cooling passage (not illustrated) may be formed in the chuck 310. The cooling passage may be formed in an interior of the chuck 310. A cooling fluid may flow in the cooling passage. The cooling fluid may be a coolant or a cooling gas. Furthermore, the configuration of cooling the chuck 310 is not limited to the configuration of supplying a cooling fluid, but may be provided with various configurations (for example, a cooling plate and the like) that may cool the chuck 310.

A height of an upper surface of a central area of the chuck 310 viewed from the top may be different from a height of an upper surface of an edge area of the chuck 310. For example, the height of the upper surface of the central area of the chuck 310 may be different from the height of the upper surface of the edge area of the chuck 310. For example, the upper surface of the chuck 310 may have a concave shape such that the height of the upper surface of the central area of the chuck 310 is lower than the height of the upper surface of the edge area of the chuck 310. Accordingly, when the substrate “W” is positioned on the chuck 310, the edge area of the chuck 310 may support the lower surface of the substrate “W”, and the central area of the chuck 310 may be spaced apart from the lower surface of the substrate “W”. That is, the central area of the chuck 310 may be spaced apart from the lower surface of the substrate “W”, and the central area of the chuck 310 and the lower surface of the substrate “W” may form a specific gap T3.

The power source member 320 may supply electric power to the chuck 310. The power source member 320 may include a power source 322, a matcher 324, and a power source line 326. The power source 322 may be a bias power source. The power source 322 may be connected to the chuck 310 by a medium of the power source line 326.

Furthermore, the matcher 324 may be provided to the power source line 326, and may perform impedance matching.

The insulation ring 330 may have a ring shape when viewed from the top. The insulation ring 330 may be configured to surround the chuck 310 when viewed from the top. For example, the insulation ring 330 may have a ring shape. Furthermore, the insulation ring 330 may have a stepped shape such that a height of an upper surface of an inner area and a height of an upper surface of an outer area thereof may be different. For example, the insulation ring 330 may be stepped such that the height of the upper surface of the inner area thereof is higher than the height of the upper surface of the outer area thereof. When the substrate “W” is seated on the support surface included in the chuck 310, the upper surface of the inner area and the upper surface of the outer area of the insulation ring 330 may be spaced apart from a bottom surface of the substrate “W”. The insulation ring 330 may be provided between the chuck 310 and the lower electrode 350, which will be described below. Because the chuck 310 is provided with a bias power source, the insulation ring 330 may be provided between the chuck 310 and the lower electrode 350, which will be described below. The insulation ring 330 may be formed of a material having an insulation property.

The lower electrode 350 may be disposed below the edge area of the substrate “W” supported by the chuck 310. The lower electrode 350 may have a ring shape when viewed from the top. The lower electrode 350 may be configured to surround the insulation ring 330 when viewed from the top. The upper surface of the lower electrode 350 may have a height that is different from an outer upper surface of the insulation ring 330. The lower surface of the lower electrode 350 may have a height that is the same as the lower surface of the insulation ring 330. Furthermore, the upper surface of the lower electrode 350 may be lower than the upper surface of the central area of the chuck 310. Furthermore, the lower electrode 350 may be spaced apart from the bottom surface of the substrate “W” supported by the chuck 310. For example, the lower electrode 350 may be spaced apart from the bottom surface of the edge area of the substrate “W” supported by the chuck 310.

The lower electrode 350 may be disposed to face an upper electrode 620, which will be described below. The lower electrode 350 may be disposed below the upper electrode 620, which will be described below. The lower electrode 350 may be grounded. The lower electrode 350 may increase a density of plasma by inducing coupling of the bias power source applied to the chuck 310. Accordingly, a treatment efficiency of the edge area of the substrate “W” may be improved.

The driving member 370 may elevate the chuck 310. The driving member 370 may include a driver 372 and a shaft 374. The shaft 374 may be coupled to the chuck 310. The shaft 374 may be connected to the driver 372. The driver 372 may elevate the chuck 310 upwards and downwards by a medium of the shaft 374.

The absorption member 390 may absorb the lower surface of the substrate “W” supported by the chuck 310. That is, the absorption member 390 may chuck the substrate “W” supported by the chuck 310 in a vacuuming absorption scheme. The absorption member 390 may include an absorption line 394 that absorbs the lower surface of the substrate “W” supported by the chuck 310, and a pressure reducing member 392 connected to the absorption line 394. The pressure reduced by the pressure reducing member 392 may be delivered to the absorption line 394, and the absorption line 394 may vacuum-absorb the substrate “W” by delivering an absorption force to the lower surface of the substrate “W”. The absorption line 394 may be a vacuum channel formed in the chuck 310.

The dielectric plate unit 500 may include a dielectric plate 520, and a first base 510. Furthermore, the dielectric plate unit 500 may be coupled to the temperature adjusting plate 700, which will be described below.

The dielectric plate 520 may be disposed to face the substrate “W” supported by the support unit 300 in the treatment space 102. For example, the lower surface of the dielectric plate 520 may be configured to face the upper surface of the substrate “W” supported by the chuck 310. The dielectric plate 520 may be disposed above the support unit 300. The dielectric plate 520 may be formed of a material including ceramics.

The dielectric plate 520 may have a circular shape when viewed from a top. A height of a lower surface of a central area of the dielectric plate 520 and a height of a lower surface of an edge area of the dielectric plate 520 when viewed from the top may be different. For example, the height of the lower surface of the central area of the dielectric plate 520 may be higher than the height of the lower surface of the edge area of the dielectric plate 520. For example, the lower surface of the dielectric plate 520 may be concave such that the height of the lower surface of the central area of the dielectric plate 520 is higher than the height of the lower surface of the edge area of the dielectric plate 520. Accordingly, when the substrate “W” is positioned on the chuck 310, an interval T1 between the upper surface of the substrate “W” and the lower surface of the central area of the dielectric plate 520 may be larger than an interval T2 between the upper surface of the substrate “W” and the lower surface of the edge area of the dielectric plate 520.

Furthermore, the upper surface of the dielectric plate 520 may be stepped such that the height of the central area thereof is higher than the height of the edge area thereof. Furthermore, a recess 524 may be formed on the upper surface of the dielectric plate 520. The recess 524 may be recessed in a direction that faces the lower surface of the dielectric plate 520 from the upper surface of the dielectric plate 520. The recess 524 may have a circular shape when viewed from the top. Furthermore, at least one ejection hole 522 may be formed in the dielectric plate 520. The ejection hole 522 may extend from the above-described recess 524 to the lower surface of the dielectric plate 520, and the first gas G1 supplied by a first gas supply part 810, which will be described below, may flow.

Furthermore, the recess 524 formed in the dielectric plate 520 may be combined with the first base 510, which will be described below, to form a buffer space. The buffer space may be a space, into which the first gas G1 supplied by the first gas supply part 810 is injected. Furthermore, the buffer space may be communicated with the above-described ejection hole 522. That is, when the first gas supply part 810 supplies the first gas G1 into the buffer space, the first gas G1 is dispersed in the buffer space and the dispersed first gas G1 may be supplied to the central area of the substrate “W” through the ejection hole 522.

Furthermore, the above-described ejection hole 522 may be a hole having a circular shape when viewed from the top. Furthermore, the ejection hole 522 may have a diameter of about 1.5 mm to about 3.0 mm. When the diameter of the ejection hole 522 is larger than 3.0 mm, the first gas G1 may be excessively supplied to the central area of the substrate “W”, and thus a treatment efficiency for the edge area of the substrate “W” may deteriorate. Furthermore, when the diameter of the ejection hole 522 is smaller than 1.5 mm, a flow rate of the first gas G1 supplied to the central area of the substrate “W” may be reduced, and thus the second gas G2 supplied to the edge area of the substrate “W” may be introduced into the central area of the substrate “W”. Accordingly, the ejection hole 522 of the dielectric plate 520 according to the embodiment of the inventive concept may have a diameter of about 1.5 mm to about 3.0 mm.

The first base 510 may be provided between the ceiling of the housing 100 and the dielectric plate 520. The first base 510 may be provided between the temperature adjusting plate 700, which will be described below, and the dielectric plate 520. The first base 510 may be coupled to the temperature adjusting plate 700, which will be described below, and the dielectric plate 520 may be coupled to the first base 510. Accordingly, the dielectric plate 520 may be coupled to the temperature adjusting plate 700 by a medium of the first base 510.

A diameter of the first base 510 may gradually increase as it goes from an upper side to a lower side. An upper surface of the first base 510 may be smaller than that of the lower surface of the dielectric plate 520. The upper surface of the first base 510 may have a flat shape. Furthermore, the lower surface of the first base 510 may have a stepped shape. For example, the lower surface of the first base 510 may be stepped such that a height of a lower surface of an edge area of the first base 510 may be lower than a height of a lower surface of a central area thereof. Furthermore, the lower surface of the first base 510 and the upper surface of the dielectric plate 520 may have shapes that may be combined with each other. For example, the central area of the dielectric plate 520 may be inserted into the central area of the first base 510. Furthermore, the first base 510 may be formed of a material including a metal. For example, the first base 510 may be formed of a material including aluminum.

The upper electrode unit 600 may include a second base 610 and the upper electrode 620. Furthermore, the upper electrode unit 600 may be coupled to the temperature adjusting plate 700, which will be described below.

The upper electrode 620 may face the above-described lower electrode 620. The upper electrode 620 may be disposed above the lower electrode 350. The upper electrode 620 may be disposed above the edge area of the substrate “W” supported by the chuck 310. The upper electrode 620 may be grounded.

The upper electrode 620 may be configured to surround the dielectric plate 520 when viewed from the top. The upper electrode 620 may be spaced apart from the dielectric plate 520. The upper electrode 620 may be spaced apart from the dielectric plate 520 to form a gap space. The gap space may form a portion of a gas channel, in which the second gas G2 supplied by a second gas supply part 830 flows. A discharge end of the gas channel may be configured such that the second gas G2 may be supplied to the edge area of the substrate “W” supported by the support unit 300. Furthermore, the discharge end of the gas channel may be configured such that the second gas G2 is supplied to the upper surface of the edge area of the substrate “W” supported by the support unit 300.

The second base 610 may be disposed between the upper electrode 620 and the temperature adjusting plate 700, which will be described below. The second base 610 may be coupled to the temperature adjusting plate 700, which will be described below, and the upper electrode 620 may be coupled to the second base 610. Accordingly, the upper electrode 620 may be coupled to the temperature adjusting plate 700 by a medium of the second base 610.

The second base 610 may have a ring shape when viewed from the top. An upper surface and a lower surface of the second base 610 may have flat shapes. The second base 610 may have a shape that surrounds the first base 510 when viewed from the top. An inner diameter of the second base 610 may gradually increase as it goes from an upper side to a lower side. The second base 610 may be spaced apart from the first base 510. The second base 610 may be spaced apart from the first base 510 to form a gap space. The gap space may form a portion of a gas channel, in which the second gas G2 supplied by the second gas supply part 830 flows. Furthermore, the second base 610 may be formed of a material including a metal. For example, the second base 610 may be formed of a material including aluminum.

The temperature adjusting plate 700 may be coupled the dielectric plate unit 500 and the upper electrode unit 600. The temperature adjusting plate 700 may be installed in the housing 100. The temperature adjusting plate 700 may generate heat. For example, the temperature adjusting plate 700 may perform heating or cooling. The temperature adjusting plate 700 may receive a signal from the controller 900, which will be described below, and generate heat. The temperature adjusting plate 700 may perform heating or cooling, and may perform a control to maintain temperatures of the dielectric plate unit 500 and the upper electrode unit 600 relatively constantly. For example, the temperature adjusting plate 700 may maximally restrain the temperatures of the dielectric plate unit 500 and the upper electrode unit 600 from excessively increasing in the process of treating the substrate “W”.

The gas supply unit 800 may supply the gas into the treatment space 102. The gas supply unit 800 may supply the first gas G1 and the second gas G2 into the treatment space 102. The gas supply unit 800 may include the first gas supply part 810 and the second gas supply part 830.

The first gas supply part 810 may supply the first gas G1 into the treatment space 102. The first gas G1 may be an inert gas such as nitrogen. The first gas supply part 810 may supply the first gas G1 to the central area of the substrate “W” supported by the chuck 310. The first gas supply part 810 may include a first gas supply source 812, a first gas supply line 814, and a first valve 816. The first gas supply source 812 may store the first gas G1 and/or supply the first gas G1 to the first gas supply line 814. The first gas supply line 814 may be connected to a passage formed in the dielectric plate 520. The first valve 816 may be installed in the first gas supply line 814. The first valve 816 may be an on/off valve or a flow rate adjusting valve. The first gas G1 supplied by the first gas supply source 812 may be supplied into the buffer space formed by combining the recess 524 of the dielectric plate 520 and the first base 510, and the first gas G1 supplied into buffer space may be supplied to the central area of the upper surface of the substrate “W” through the ejection hole 522.

The second gas supply part 830 may supply the second gas G2 into the treatment space 102. The second gas G2 may be a process gas excited into the plasma state. The second gas supply part 830 may supply the second gas G2 to the edge area of the substrate “W” through the gas channel formed by spacing the dielectric plate 520 provided above the edge area of the substrate “W” supported by the chuck 310, the first base 510, the upper electrode 620, and the second base 610 apart from each other. The second gas supply part 830 may include a second gas supply source 832, a second gas supply line 834, and a second valve 836. The second gas supply source 832 may store the second gas G2 and/or supply the second gas G2 to the second gas supply line 834. The second gas supply line 834 may supply the second gas G2 to a gap space that functions as a gas channel. The second valve 836 may be installed in the second gas supply line 834. The second valve 836 may be an on/off valve or a flow rate adjusting valve. The second gas G2 supplied by the second gas supply source 832 may be supplied to the edge area of the upper surface of the substrate “W” though the gas channel formed by the first base 510 and the second base 610, and the gas channel formed by the dielectric plate 520 and the upper electrode 620.

The controller 900 may control the substrate treating apparatus. The controller 900 may control the substrate treating apparatus to perform a plasma treatment process that will be performed as follows. For example, the controller 900 may control the gas supply unit 800, the temperature adjusting plate 700, and the support unit 300. For example, the controller 900 may control the support unit 300 and the gas supply unit 800 such that plasma “P” is generated in the edge area of the substrate “W” supported by the chuck 310 applying electric power to the chuck 310 with the power source 322 when the first gas supply part 810 and/or the second gas supply part 830 supplies the gas.

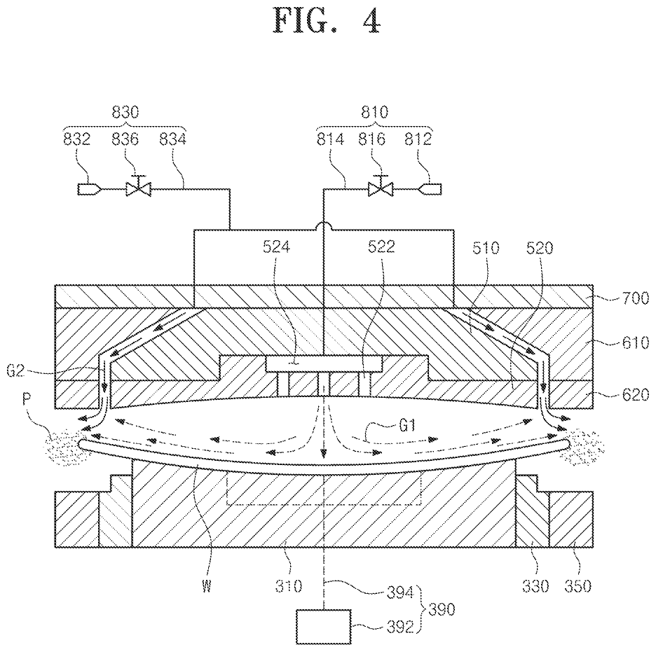

FIG. 4 is a view illustrating an embodiment of performing a plasma treatment process by the substrate treating apparatus of FIG. 3. Referring to FIG. 4, the substrate treating apparatus according to the embodiment of the inventive concept may treat the edge area of the substrate “W”. For example, the substrate treating apparatus may treat the edge area of the substrate “W” by generating the plasma “P” in the edge area of the substrate “W”. For example, the substrate treating apparatus may perform a bevel etching process of treating the edge area of the substrate “W”. The substrate treating apparatus may supply the first gas G1 to the central area of the substrate “W” with the first gas supply part 810 when the edge area of the substrate “W” is treated, and supply the second gas G2 to the edge area of the substrate “W” with the second gas supply part 830. Because the second gas G2 supplied by the second gas supply part 830 is a process gas, it may be excited into a plasma (P) state and may treat the edge area of the substrate “W”. For example, the thin film on the edge area of the substrate “W” may be etched by the plasma “P”. Furthermore, the first gas G1 supplied to the central area of the substrate “W” is an inert gas, and the first gas G1 may further increase the treatment efficiency for the edge area of the substrate “W” by preventing the second gas G2 from being introduced into the central area of the substrate “W”. Furthermore, the temperature adjusting plate 700 may perform cooling such that temperatures of the dielectric plate unit 500 and the upper electrode unit 600 may be restrained from excessively increasing while the treatment for the substrate “W” is performed.

According to the embodiment of the inventive concept, the height of the central area of the dielectric plate 520 may be higher than the height of the edge area of the dielectric plate 520. Accordingly, an interval between the upper surface of the substrate “W” and the lower surface of the dielectric plate 520 may become narrow as it goes from the central area to the edge area of the substrate “W”. Accordingly, a flow velocity of the first gas G1 supplied to the central area of the substrate “W” becomes faster as it goes to the edge area of the substrate “W”. Accordingly, the first gas G1 may effectively push out the second gas G2 introduced into the central area of the substrate “W” to an outer area of the substrate “W”. Furthermore, the height of the upper surface of the central area of the chuck 310 according to the inventive concept is lower than the height of the upper surface of the edge area of the chuck 310. Accordingly, when the substrate “W” supported by the chuck 310 is chucked by the absorption member 390, an interval between the upper surface of the substrate “W” and the lower surface of the dielectric plate 520 may be further narrower as it goes from the central area to the edge area of the substrate “W”. Accordingly, the flow velocity of the first gas G1 supplied to the central area of the substrate “W” may become further faster. Accordingly, the first gas G1 may effectively push out the second gas G2 introduced into the central area of the substrate “W” to an outer area of the substrate “W”. That is, according to the embodiment of the inventive concept, even though the flow rate of the first gas G1 is not significantly increased, the second gas G2 may be effectively restrained from being introduced into the central area of the substrate “W”.

Furthermore, the upper surface of the chuck 310 may have a concave shape.

Accordingly, when the substrate “W” seated on the chuck 310 is chucked by the absorption member 390, the substrate “W” may be slightly deformed (FIG. 4 illustrates in a way that is exaggerated as compared with the reality to illustrate the gist of the inventive concept more clearly). Accordingly, the first gas G1 supplied onto the upper surface of the substrate “W” may flow along the edge area of the substrate “W”, and the first gas G1 may flow in an upwardly inclined direction. Because the second gas G2 flows in a direction that faces a lower side from the top, the second gas G2 may be effectively restrained from being introduced into the central area of the substrate “W” when the first gas G1 flows in the upwardly inclined direction. Accordingly, the treatment efficiency of the edge area of the substrate “W” may be further increased.

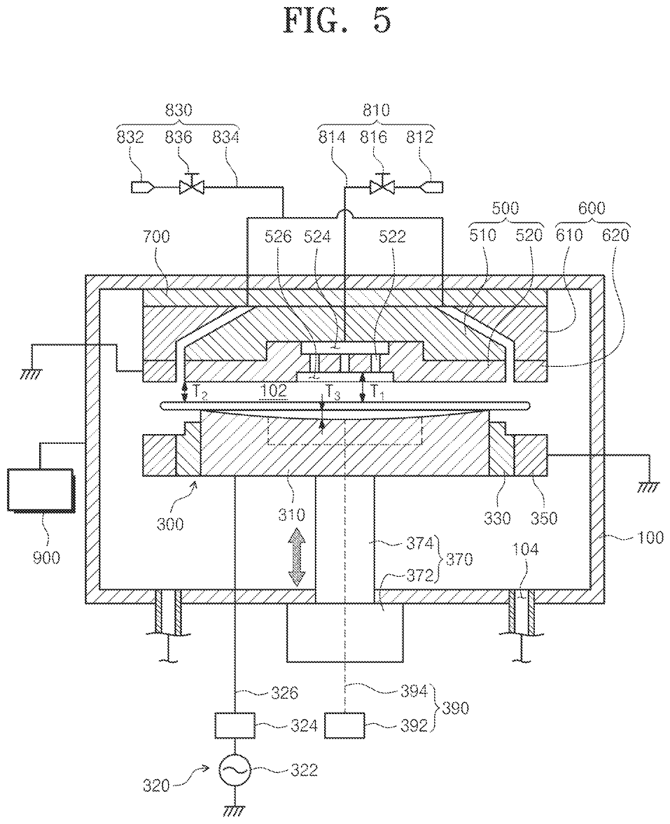

Although it has been described in the above-described example that the lower surface of the dielectric plate 520 has a concave shape, the inventive concept is not limited thereto. For example, as illustrated in FIG. 5, the lower surface of the dielectric plate 520 is flat and a recess 526 may be formed in the central area thereof. That is, the lower surface of the dielectric plate 520 may be stepped such that the height of the lower surface of the central area of the dielectric plate 520 is higher than the height of the lower surface of the edge area of the dielectric plate 520.

Although it has been described as an example that the substrate treating apparatus performs an etching process on the edge area of the substrate “W”, the inventive concept is not limited thereto. The above-described embodiments may be applied to various facilities and processes that require treatments for the edge area of the substrate “W” in the same or similar ways.

A method for generating plasma “P” by the substrate treating apparatus described in the above-described example may be an inductive coupled plasma (ICP) method. A method for generating plasma “P” by the above-described substrate treating apparatus may be a capacitor coupled plasma (CCP) method. Furthermore, the substrate treating apparatus may generate plasma “P” by using both of the inductive coupled plasma (ICP) method and the capacitor coupled plasma (CCP), or by using one selected from the inductive coupled plasma (ICP) method and the capacitor coupled plasma (CCP). Furthermore, the substrate treating apparatus may treat the edge area of the substrate “W” through a known method for generating plasma “P”, in addition to the above-described methods.

According to an embodiment of the inventive concept, the substrate may be efficiently treated.

Furthermore, according to an embodiment of the inventive concept, a process gas supplied to an edge area of a substrate may be minimized from being introduced into a central area of the substrate even though a flow rate of an inert gas supplied to the central area of the substrate is not increased

Furthermore, according to an embodiment of the inventive concept, a treatment efficiency for an edge area of a substrate may be minimized from deteriorating as a ratio of a process gas per unit volume deteriorates in the edge area of the substrate

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a housing having a treatment space;
a support unit including a chuck configured to support a substrate in the treatment space;
a gas supply unit including a first gas supply part configured to supply an inert gas to a central area of the substrate supported by the chuck, and a second gas supply part configured to supply a process gas excited into a plasma state to an edge area of the substrate supported by the chuck; and
a dielectric plate configured to face an upper surface of the substrate supported by the chuck,
wherein a height of a lower surface of a central area of the dielectric plate and a height of a lower surface of an edge area of the dielectric plate are different, and
wherein a height of an upper surface of a central area of the chuck and a height of an upper surface of an edge area of the chuck are different.

2. The substrate treating apparatus of claim 1, wherein the height of the lower surface of the central area of the dielectric plate is higher than the height of the lower surface of the edge area of the dielectric plate.

3. The substrate treating apparatus of claim 1, wherein the height of the upper surface of the central area of the chuck is lower than the height of the upper surface of the edge area of the chuck are different.

4. The substrate treating apparatus of claim 1, wherein the height of the lower surface of the central area of the dielectric plate is higher than the height of the lower surface of the edge area of the dielectric plate, and
wherein the height of the upper surface of the central area of the chuck is lower than the height of the upper surface of the edge area of the chuck.

5. The substrate treating apparatus of claim 1, wherein the upper surface of the chuck is concave such that the height of the upper surface of the central area of the chuck is lower than the height of the upper surface of the edge area of the chuck.

6. The substrate treating apparatus of claim 1, wherein the lower surface of the dielectric plate is concave such that the height of the lower surface of the central area of the dielectric plate is higher than the height of the lower surface of the edge area of the dielectric plate.

7. The substrate treating apparatus of claim 1, wherein the lower surface of the dielectric plate is stepped such that the height of the lower surface of the central area of the dielectric plate is higher than the height of the lower surface of the edge area of the dielectric plate.

8. The substrate treating apparatus of claim 1, wherein the dielectric plate includes:
a recess that is recessed in a direction that faces the lower surface of the dielectric plate from the upper surface of the dielectric plate; and
at least one ejection hole that extends from the recess to the lower surface of the dielectric plate, and through which the inert gas supplied by the first gas supply part flows.

9. The substrate treating apparatus of claim 8, further comprising:
a base provided between the dielectric plate and a ceiling of the housing,
wherein the recess and the base are combined with each other to form a buffer space, and
wherein the buffer space is communicated with the ejection hole.

10. The substrate treating apparatus of claim 9, wherein the first gas supply part supplies the process gas into the buffer space.

11. The substrate treating apparatus of claim 8, wherein the ejection hole has a diameter of 1.5 mm to 3.0 mm.

12. The substrate treating apparatus of claim 1, wherein the support unit includes:
an absorption line configured to absorb the lower surface of the substrate supported by the chuck; and
a pressure reduction member connected to the absorption line.

13. The substrate treating apparatus of claim 12, further comprising:
an upper electrode configured to surround the dielectric plate when viewed from a top,
wherein the support unit includes:
a lower electrode configured to surround the chuck when viewed from the top, and configured to face the upper electrode.

14. A substrate treating apparatus comprising:
a housing having a treatment space;
a support unit including a chuck configured to support a substrate in the treatment space;
a gas supply unit including a first gas supply part configured to supply an inert gas to a central area of the substrate supported by the chuck, and a second gas supply part configured to supply a process gas excited into a plasma state to an edge area of the substrate supported by the chuck; and
a dielectric plate configured to face an upper surface of the substrate supported by the chuck,
wherein a lower surface of the dielectric plate is concave such that a height of a lower surface of a central area of the dielectric plate is higher than a height of a lower surface of an edge area of the dielectric plate.

15. The substrate treating apparatus of claim 14, wherein a height of an upper surface of a central area of the chuck is lower than a height of an upper surface of an edge area of the chuck.

16. The substrate treating apparatus of claim 15, wherein an upper surface of the chuck is concave such that the height of the upper surface of the central area of the chuck is lower than the height of the upper surface of the edge area of the chuck.

17. The substrate treating apparatus of claim 14, wherein the support unit includes:
an absorption line configured to absorb a lower surface of the substrate supported by the chuck; and
a pressure reduction member connected to the absorption line.

18. The substrate treating apparatus of claim 17, further comprising:
an upper electrode configured to surround the dielectric plate when viewed from a top,
wherein a lower electrode configured to surround the chuck when viewed from the top, and configured to face the upper electrode.

19. The substrate treating apparatus of claim 18, wherein the chuck is connected to an RF power source, and the upper electrode and the lower electrode are grounded.

20. The substrate treating apparatus of claim 18, wherein the support unit further includes:
an insulation ring provided between the lower electrode and the chuck, and
wherein the insulation ring has a stepped shape, a height of an upper surface of an inner area of which is higher than a height of an upper surface of an outer area thereof.
